(19) United States
(12) Patent Application Publication
(10) Pub. No.: US 2025/0275240 A1
(43) Pub. Date: Aug. 28, 2025

(54) TRANSISTOR AND DISPLAY DEVICE INCLUDING THE SAME

(71) Applicant: LG Display Co., Ltd., Seoul (KR)

(72) Inventors: Do Hun KWAK, Paju-si (KR); Deuk Ho YEON, Paju-si (KR); Dae Hwan KIM, Paju-si (KR)

(73) Assignee: LG Display Co., Ltd., Seoul (KR)

(21) Appl. No.: 19/065,817

(22) Filed: Feb. 27, 2025

(30) Foreign Application Priority Data
Feb. 28, 2024 (KR) 10-2024-0029199

(51) Int. Cl. H10D 86/40; H10D 30/67

(52) U.S. Cl. CPC H10D 86/423; H10D 30/6755; H10D 86/441

(57) ABSTRACT

A transistor can include an active layer having a first active layer, a second active layer, and a third active layer that are sequentially stacked. The transistor can further include a gate electrode overlapping the active layer, and a gate insulating film between the active layer and the gate electrode. The second active layer has the highest mobility in the active layer. In the transistor, an upper surface and a side surface of the second active layer are surrounded by the third active layer.

### CROSS-REFERENCE TO RELATED APPLICATIONS

This application claims priority to Korean Patent Application No. 10-2024-0029199, filed in the Republic of Korea on Feb. 28, 2024, the entire contents of which are hereby expressly incorporated by reference into the present application.

### BACKGROUND

### Field

The present disclosure relates to a transistor, and more particularly, to a transistor capable of improving reliability and a display device including the same.

### Discussion of the Related Art

Various methods and forms have been used for a display device that displays an image on a TV, a monitor, a smartphone a tablet computer, a notebook computer, etc.

The display device includes a plurality of pixels to implement an image and has a transistor to control an operation of each pixel.

The display device includes a plurality of pixels and has a plurality of driving and switching elements to drive and control the pixels. The driving and switching elements can include transistors, and the transistors are widely applied not only to the pixels but also to integrated circuits.

Recently, various research and development has been conducted to improve performance and reliability of these transistors.

### SUMMARY OF THE DISCLOSURE

Accordingly, the present disclosure is directed to a transistor and a display device including the same that substantially obviate one or more problems due to limitations and disadvantages of the related art.

A technical aspect of embodiments of the present disclosure is to implement a transistor including a heterogeneous material in an active layer while preventing or minimizing a change in effective channel length.

A technical aspect of embodiments of the present disclosure is to improve reliability of a transistor including an oxide semiconductor by controlling a change in effective channel length of the transistor.

A technical aspect of embodiments of the present disclosure is to provide a wide-width transistor capable of preventing or reducing a change in effective channel length due to Joule heat generation in a structure having a wide channel width, thereby preventing or minimizing a change in threshold voltage due to the change in effective channel length.

A technical challenge of embodiments of the present disclosure is to provide a display device including a wide-width transistor having device stability in an active area or a non-active area.

A technical aspect of embodiments of the present disclosure is to reduce sensitivity according to channel width changes, thereby increasing design freedom and implementing a narrow bezel by placing a high-power transistor in a non-active area with a small size for the same output.

A technical aspect of embodiments of the present disclosure is to provide a display device capable of reducing greenhouse gases generated during a manufacturing process since production of materials used throughout the manufacturing process, such as gas and etching liquid, to manufacture the display device can be reduced by reducing a defect rate of the display device.

Additional advantages, objects, and features of the disclosure will be set forth in part in the description which follows and in part will become apparent to those having ordinary skill in the art upon examination of the following or can be learned from practice of the disclosure. The objectives and other advantages of the disclosure can be realized and attained by the structure particularly pointed out in the written description and claims hereof as well as the appended drawings.

To achieve these objects and other advantages and in accordance with the purpose of the disclosure, as embodied and broadly described herein, a transistor includes an active layer including a first active layer, a second active layer, and a third active layer that are sequentially stacked, a gate electrode overlapping the active layer, and a gate insulating film between the active layer and the gate electrode, wherein the second active layer has a highest mobility among layers of the active layer.

It is to be understood that both the foregoing general description and the following detailed description of the present disclosure are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure. In the drawings:

FIG. 1 is a schematic plan view illustrating a display device according to one or more embodiments of the present disclosure;

FIG. 2 is a circuit diagram illustrating a subpixel according to an embodiment of the present disclosure;

FIG. 3 is a circuit diagram illustrating a configuration of a gate-in-panel (GIP) according to an embodiment of the present disclosure;

FIG. 4 is a plan view illustrating an active layer of a transistor according to an embodiment of the present disclosure;

FIG. 5 is a cross-sectional view illustrating a transistor taken along line I-I′ of FIG. 4 according to a first embodiment of the present disclosure;

FIG. 6 is a cross-sectional view illustrating a conductive region in a multilayer configuration of an active layer of a transistor of a first experimental example;

FIG. 7 is a cross-sectional view illustrating a conductive region in a multilayer configuration of an active layer of a transistor of a second experimental example;

FIG. 8 is a cross-sectional view illustrating a transistor according to a second embodiment of the present disclosure;

FIG. 9 is a plan view illustrating a transistor according to a third embodiment of the present disclosure;

FIG. 10 is a cross-sectional view taken along line II-II′ of FIG. 9;

FIG. 11 is a cross-sectional view taken along line III-III′ of FIG. 9;

FIG. 12 is a graph illustrating I-V characteristics of transistors of first to third experimental examples; and

FIG. 13 is a cross-sectional view illustrating a display device according to an embodiment of the present disclosure.

### DETAILED DESCRIPTION OF THE EMBODIMENTS

Hereinafter, example embodiments of the present disclosure will be described with reference to the attached drawings. The same reference numerals throughout the specification represent substantially the same components. In the following description of the present disclosure, where the detailed description of the relevant known steps, elements, functions, technologies, and configurations can unnecessarily obscure an important point of the present disclosure, a detailed description of such steps, elements, functions, technologies, and configurations can be omitted. In addition, the names of elements used in the following description are selected in consideration of clarity of description of the specification, and can differ from the names of elements of actual products.

The shapes, sizes, ratios, angles, numbers, and the like, which are illustrated in the drawings to describe various example embodiments of the present disclosure are merely given by way of example. The disclosure is not limited to the illustrations in the drawings. In the present disclosure, where terms such as “including,” “having,” “comprising,” and the like are used, one or more components can be added, unless the term, such as “only,” is used. The terminology used herein is to describe particular aspects and is not intended to limit the present disclosure. As used herein, the terms “a” and “an” used to describe an element in the singular form is intended to include a plurality of elements. An element described in the singular form is intended to include a plurality of elements, and vice versa, unless the context clearly indicates otherwise.

In construing a component or numerical value, the component or the numerical value is to be construed as including an error or tolerance range even where no explicit description of such an error or tolerance range is provided.

In describing the various example embodiments of the present disclosure, where the positional relationship between two elements is described using terms, such as “on”, “above”, “over,” “below,” “under” and “next to”, etc., at least one intervening element can be present between the two elements, unless “immediate(ly)” or “direct(ly)” or “close(ly) is used. It will be understood that when an element or layer is referred to as being “connected to”, or “coupled to” another element or layer, it can be directly connected to or coupled to the other element or layer, or one or more intervening elements or layers can be present.

In describing the various example embodiments of the present disclosure, when terms such as “after,” “subsequently,” “next,” and “before,” are used to describe the temporal relationship between two events, another event can occur therebetween, unless a more limiting term, such as “just,” “immediate(ly),” or “directly” is used.

In describing the various example embodiments of the present disclosure, terms such as “first” and “second” can be used to describe a variety of components. These terms aim to distinguish the same or similar components from one another and do not limit the components, and may not define order or sequence. Accordingly, throughout the specification, a “first” component can be the same as a “second” component within the technical concept of the present disclosure, unless specifically mentioned otherwise.

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in a co-dependent relationship. Further, the term “can” fully encompasses all the meanings and coverages of the term “may.”

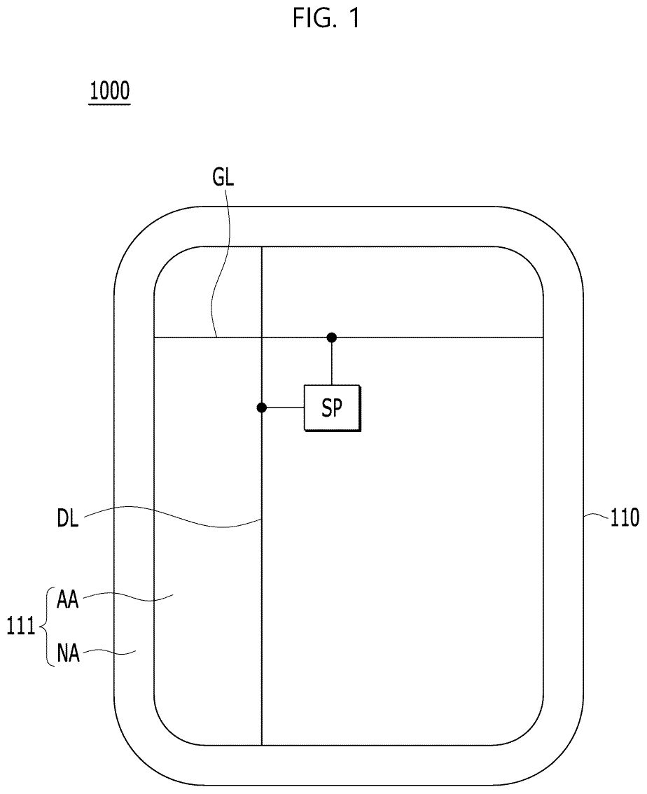

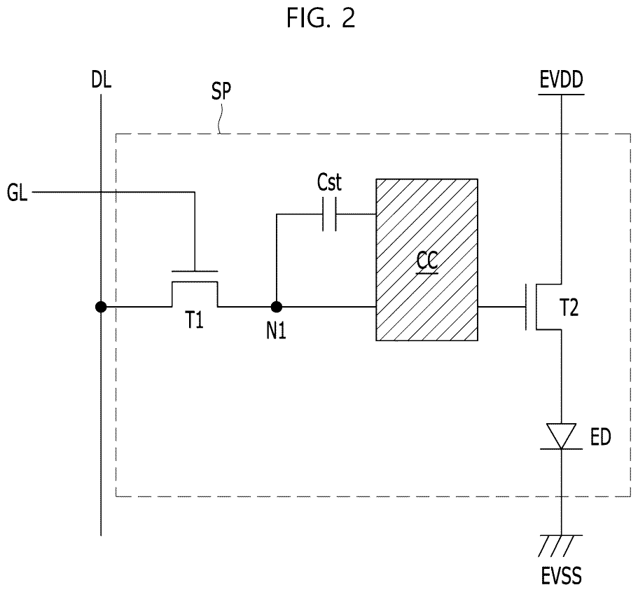

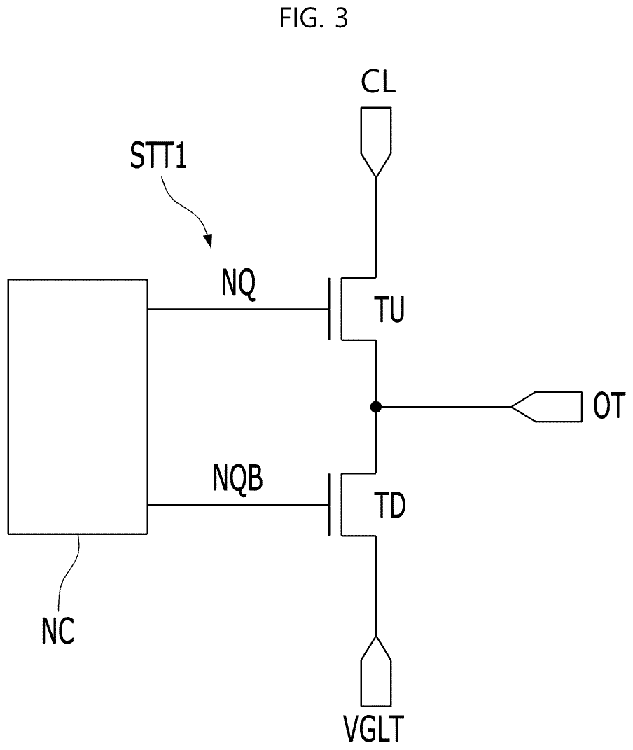

FIG. 1 is a schematic plan view illustrating a display device according to one or more embodiments of the present disclosure, FIG. 2 is a circuit diagram illustrating a subpixel according to an embodiment of the present disclosure, and FIG. 3 is a circuit diagram illustrating a configuration of a GIP according to an embodiment of the present disclosure.

Referring to FIGS. 1 and 2, a display device 1000 according to an embodiment of the present disclosure can include a display panel 110 and a case that accommodates a side surface of the display panel 110 and a lower part of the display panel 110. A non-active area NA (or non-display area) of the display panel 110 can be hidden by the case or covered by a separate light blocking film. A printed circuit film and/or a battery can be included between the lower part of the display panel 110 and the case.

The display panel 110 can include a substrate 111 including an active area AA (or display area) and the non-active area NA surrounding the active area AA, and a drive unit connected to the substrate 111. The non-active area NA can surround the active area AA entirely or only in part(s). The drive unit can be integrated and formed in the substrate 111 together with a component of an array provided in the active area AA, or can be connected to the substrate 111 using a COG (Chip On Glass) method, or can be connected to a printed circuit board through a film or connector using a COF (Chip On Film) method on the substrate 111. Alternatively, the drive unit can also include a component integrated in the substrate 111 and an external component of a COG or a COF.

The active area AA is an area in which an image is displayed. A plurality of subpixels SP is arranged in the active area AA of the display panel 110, and an image can be displayed using the plurality of subpixels SP. An area other than the active area AA can be a non-active area NA.

The non-active area NA can be arranged in an edge region surrounding the active area AA in which an image is displayed. At least one drive unit for driving the plurality of subpixels SPs can be arranged in the non-active area NA. The drive unit can include a GIP. The GIP is connected to a plurality of gate lines GLs in the active area AA and can sequentially supply gate voltage signals to the plurality of gate lines GLs.

In the non-active area NA, various additional elements can be further arranged to drive subpixels SPs in the active area AA.

At least one subpixel SP among the plurality of pixels can include a first transistor T1, a second transistor T2, a storage capacitor Cst, a compensation circuit CC, and a light emitting element ED, as shown in FIG. 2.

For example, the first transistor T1 can be a switching transistor, and the second transistor T2 can be a driving transistor.

The first transistor T1 has a first electrode (for example, a drain electrode) electrically connected to a data line DL, and a second electrode (for example, a source electrode) electrically connected to a first node N1. A gate electrode of the first transistor T1 is electrically connected a gate line GL. In response to a scan signal supplied through the gate line GL, the first transistor T1 transmits a data signal supplied through the data line DL to the first node N1.

A storage capacitor Cst is electrically connected to the first node N1 and charged with a voltage applied to the first node N1.

The second transistor T2 has a first electrode (for example, a drain electrode) to which a high-potential driving voltage EVDD is applied, and a second electrode (for example, a source electrode) electrically connected to a first electrode (for example, an anode) of the light emitting element ED. The second transistor T2 can control the amount of driving current flowing to the light emitting element ED according to a voltage difference between the gate electrode and the source electrode.

A semiconductor layer of the first transistor T1 or/and the second transistor T2 can include silicon such as amorphous silicon (a-Si), polycrystalline silicon (poly-Si), or low-temperature polycrystalline silicon (poly-Si), or can include an oxide semiconductor.

The transistor and the display device of the embodiments of the present disclosure can have advantages of including an oxide semiconductor layer in at least one of the transistors formed on the substrate 111, enabling formation at a relatively low temperature compared to other materials, maintaining amorphous characteristics, and having a high mobility.

The light emitting element ED outputs light corresponding to a driving current. The light emitting element ED can output light corresponding to any one of red, green, blue, and white.

The light emitting element ED can include the anode, an intermediate layer disposed on the anode, and a cathode supplied with a common voltage (e.g., EVSS). The intermediate layer includes at least one light emitting layer, and when an electric field is formed between the anode and the cathode, the intermediate layer can be implemented to emit light of the same color for each pixel, such as white light, or can be implemented to emit different colors for each subpixel SP, such as red, green, and blue light. The intermediate layer can include various types of common layers and functional layers together with the light emitting layer to efficiently supply holes and electrons to the light emitting layer.

The light emitting element ED can be a front emitting diode or a back emitting diode.

The compensation circuit CC can be additionally provided in the subpixel SP to compensate for a threshold voltage, etc., of the second transistor T2. The compensation circuit CC can include one or more transistors. The compensation circuit CC can include one or more transistors and capacitors, and can be configured in various ways depending on the compensation method. A subpixel SP including the compensation circuit CC can include circuits of various structures having different numbers of transistors and/or capacitors, such as 3T1C, 4T2C, 5T2C, 6TIC, 6T2C, 7TIC, and 7T2C.

Among the transistors provided in the subpixel, the switching transistor can require high-speed driving for fast switching operation. The driving transistor can supply high current to the light emitting element and require high current output for high luminance expression.

The GIP included in the non-active area NA outputs gate signals to gate lines according to a gate control signal input from, for example, a timing controller. The GIP can include a plurality of transistors, and the plurality of transistors can be formed in the same process as that of the transistors of the subpixel SP.

For example, the GIP can include stages STT1 that are dependently connected, as shown in FIG. 3, and the stages STT1 can sequentially output gate signals to the gate lines.

Referring to FIG. 3, each of the stages STT1 includes a pull-up node NQ, a pull-down node NQB, a pull-up transistor TU that turns on when the pull-up node NQ is charged with a gate high voltage, a pull-down transistor TD that turns on when the pull-down node NQB is charged with a gate high voltage, and a node controller NC for controlling charging and discharging of the pull-up node NQ and the pull-down node NQB.

The node controller NC can be connected to a start signal line to which a start signal or a carry signal of a previous stage is input, and a clock line to which one of gate clock signals is input. The node controller NC controls charging and discharging of the pull-up node NQ and the pull-down node NQB according to the start signal or the carry signal of the previous stage input to the start signal line and the gate clock signal input to the clock line. To stably control output of the stage STT1, the node controller discharges the pull-down node NQB to the gate low voltage when the pull-up node NQ is charged with the gate high voltage, and discharges the pull-up node NQ to the gate low voltage when the pull-down node NQB is charged to the gate high voltage. To this end, the node controller NC can include a plurality of transistors.

The pull-up transistor TU is turned on when the stage STT1 is pulled up, for example, when the pull-up node NQ is charged with the gate high voltage, and outputs the gate clock signal of the clock line CL to an output terminal OT. The pull-down transistor TD is turned on when the stage STT1 is pulled down, that is, when the pull-down node NQB is charged with the gate high voltage, and discharges the output terminal OT to a gate low voltage of a gate low voltage terminal VGLT.

In FIG. 3, the pull-up transistor TU, the pull-down transistor TD, and the plurality of transistors of the node controller NC of each stage STT1 of the GIP can be transistors having wide channel widths for high response speed and high-voltage output of a high-voltage gate.

In addition, FIG. 2 and FIG. 3 illustrate that the transistors T1 and T2 of the subpixel SP and the pull-up transistor TU, the pull-down transistor TD, and the plurality of transistors of the node controller NC of each stage STT1 of the GIP are formed as N-type semiconductor transistors having N-type semiconductor characteristics. However, embodiments of the present disclosure are not limited thereto. For example, at least one of the transistors T1 and T2 of the subpixel SP and the pull-up transistor TU, the pull-down transistor TD, and the plurality of transistors of the node controller NC of each stage STT1 of the GIP can be formed as a P-type semiconductor transistor having P-type semiconductor characteristics.

The display panel 110 can include a data drive unit in addition to the GIP. For example, the data drive unit can include at least one source drive integrated circuit (hereinafter referred to as “IC”). The source drive IC receives input of digital video data and a source control signal from the timing controller. The source drive IC converts the digital video data into analog data voltages according to the source control signal and supplies the converted analog data voltages to data lines DL.

When the source drive IC is formed as a driving chip such as an integrated circuit, the source drive IC can be mounted on a flexible film using a COF (chip on film) method. Wires connecting pads and the source drive IC, and wires connecting the pads and wires of the circuit board are formed on the flexible film. The flexible film is attached to pads such as data pads formed in the non-display area NA of the display panel DP using an anisotropic conducting film, so that the pads and the wires of the flexible film can be connected.

Active layers of transistors are formed by oxide semiconductor layers, thereby omitting high-temperature crystallization and having a certain level of mobility. In addition, considering environmental pollution caused by the high-temperature process, a recent display device is formed by including an oxide semiconductor layer, which omits the high-temperature crystallization process and has an advantage of easy material accessibility.

Hereinafter, according to one or more embodiments of the present disclosure, a specific description will be given of a thin film transistor having an oxide semiconductor layer applicable to transistors of subpixels (SPs) of a display device requiring high-speed operation due to high resolution, transistors of the GIP, etc.

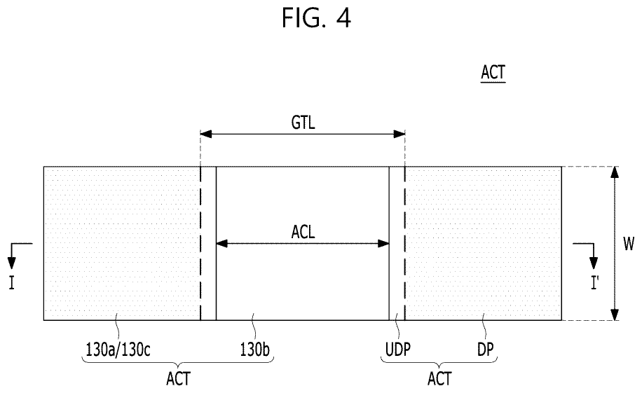

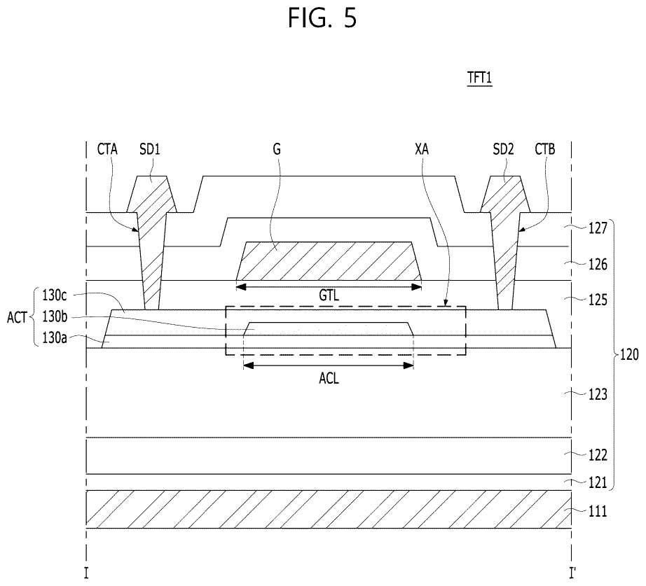

FIG. 4 is a plan view illustrating an active layer of a transistor according to an embodiment of the present disclosure, and FIG. 5 is a cross-sectional view illustrating a transistor taken along line I-I′ of FIG. 4 according to a first embodiment of the present disclosure.

Referring to FIGS. 4 and 5, a transistor TFT1 according to the first embodiment of the present disclosure includes an active layer ACT including a first active layer 130a, a second active layer 130b, and a third active layer 130c that are sequentially stacked, a gate electrode G overlapping the active layer ACT, and a gate insulating film 125 between the active layer ACT and the gate electrode G.

Among the first to third active layers 130a, 130b, 130c provided in the active layer ACT, the second active layer 130b can have the highest mobility.

The second active layer 130b located in a middle layer in the active layer ACT and having a high mobility can function as a main channel. The active layer ACT can stably function since the second active layer 130b, which is a main channel, is protected by the first and third active layers 130a and 130c. Here, when the second active layer 130b applies a gate voltage to the gate electrode G, the active layer ACT is switched depending on the mobility of the second active layer 130b having a high mobility. Accordingly, a flow of charges can occur in the second active layer 130b in a region overlapping the gate electrode G. The transistor TFT1 according to the first embodiment of the present disclosure can shorten a charge (carrier) movement length by arranging the high-mobility second active layer 130b in a region where a flow of charges occurs. In this case, the transistor TFT1 has high response speed and can be driven with low power due to high-mobility properties of the second active layer 130b and a short length ACL2 of the second active layer 130b functioning as a channel.

Here, the length ACL of the high-mobility second active layer 130b disposed between a first source-drain electrode SD1 and a second source-drain electrode SD2 can function as a channel as a whole, and the channel can have high-mobility characteristics and increase a response speed of the transistor TFT1. Accordingly, the transistor TFT1 can operate with a high response speed.

The first active layer 130a and the third active layer 130c have a relatively lower mobility than that of the second active layer 130b. The first and third active layers 130a and 130c can have the same mobility. In some cases, the first and third active layers 130a and 130c can have different mobilities.

The transistor TFT1 according to the first embodiment of the present disclosure is designed so that the first and third active layers 130a and 130c have the same mobility, and thus there is no difference in characteristics at a junction of the two layers 130a and 130c and the two layers 130a and 130c have the same characteristics. In particular, the region of the first and third active layers 130a and 130c away from the gate electrode G has the same conductive characteristics in a region overlapped with a doping region DP doped with the same impurity.

The active layer ACT undergoes an impurity doping process using the gate electrode G as a mask, and as shown in FIGS. 4 and 5, a region outside the gate electrode G can be a doping region DP doped with impurities. The region of the active layer ACT overlapping with the gate electrode G is an intrinsic region UDP.

The gate electrode G overlaps part of the active layer ACT with a first length GTL and a first width W. The first length GTL and the first width W are arranged in directions intersecting each other. The gate electrode G overlaps the active layer ACT over the entire width thereof, and the first width W of the overlapping region of the gate electrode G and the active layer ACT can be equal to the entire width of the active layer ACT.

Referring to FIGS. 4 and 5, a plane of the active layer ACT includes the intrinsic region UDP overlapping the gate electrode G and the doping region DP doped with impurities that does not overlap the gate electrode G. The second active layer 130b is arranged in the intrinsic region UDP, which has the length ACL smaller than the first length GTL in which the gate electrode G overlaps the active layer ACT. Accordingly, the second active layer 130b is spaced apart from an edge of the gate electrode G and is located inside the edge of the gate electrode G in a direction of the first length GTL of the gate electrode G.

When the gate electrode G is used as a mask to dope impurities, a region of the active layer ACT away from the gate electrode G becomes the doping region DP. Since in the active layer ACT of the transistor TFT1 according to the first embodiment of the present disclosure, the second active layer 130b having a high mobility is positioned at an inside region than the first length GTL of the gate electrode G, thus the entire second active layer 130b overlaps the gate electrode G, and an edge of the second active layer 130b can be positioned inside the gate electrode G. Accordingly, the second active layer 130b is not doped with impurities and serves as the intrinsic region UDP, and the entire second active layer 130b can function as a channel.

The second active layer 130b may be disposed within the first length GTL of the gate electrode G along a channel length direction.

Meanwhile, since the gate electrode G is used as a mask in an initial state of the impurity doping process, a boundary between the intrinsic region UDP and the doping region DP can occur in a region of the active layer ACT overlapping the edge of the gate electrode G. Since the second active layer 130b is positioned apart from the doping region DP, the doping region DP can be created only for the first active layer 130a and the third active layer 130c. Accordingly, even when impurities included in the first and third active layers 130a and 130c diffuse toward the intrinsic region UDP side due to heat generation in the active layer ACT during heat treatment or operation during the process, the second active layer 130b which is spaced apart from the edge of the gate electrode G and has a different mobility is hardly affected by the diffusion, and accordingly, in the active layer ACT, it is possible to prevent a reduction in the effective length of the channel of at least the second active layer 130b and to ensure a certain effective length or more of the channel.

According to the first embodiment of the present disclosure, the transistor TFT1 can be configured such that an upper surface and a side surface of the second active layer 130b in the active layer ACT are surrounded by the third active layer 130c, and the second active layer 130b can be protected by the third active layer 130c. In addition, the third active layer 130c on a side surface of the second active layer 130b can be in contact with the first active layer 130a. In this case, different active layers having low mobilities are positioned on upper, side, and lower parts of the second active layer 130b, and thus a protection function for the second active layer 130b can be enhanced.

The third active layer 130c has a lower mobility than that of the second active layer 130b, and thus can have a low degree of impurity diffusion in terms of physical properties when the transistor TFT1 is operated. In addition, the doping region DP due to the initial impurity doping is created only in the first active layer 130a and the third active layer 130c having a low mobility. Even when impurity diffusion occurs at a boundary between the doping region DP and a non-doping region UDP, it is difficult for impurities included in the first and third active layers 130a and 130c to diffuse into the second active layer 130b which has different physical properties from those of the first and third active layers 130a and 130c and a short “ACL” length. Accordingly, since the channel of the second active layer 130b does not experience conductive diffusion, the active layer ACT can ensure an effective channel length at least in the length ACL of the second active layer 130b.

Meanwhile, the second active layer 130b can have the same width as that of the first and third active layers 130a and 130c in a width direction. Conductive diffusion mainly occurs at the boundary between the doping region DP and the intrinsic region UDP. In the active layer ACT, a channel is present where the gate electrode G overlaps the active layer ACT over the entire width W. The channel of the active layer ACT has the intrinsic region UDP. Thus, the active layer ACT has the intrinsic region UDP in the entire width W of the active layer ACT wherein the channel is present. Since there is no boundary between the doping region DP and the intrinsic region UDP in the active layer along a width direction of the active layer, and thus the width W of the active layer ACT at the channel is hardly affected by the conductive diffusion.

The first to third active layers 130a, 130b, and 130c can each include an oxide semiconductor material. In addition, the oxide semiconductor material can include an oxide semiconductor including one or more metals.

The second active layer 130b is a high-mobility active layer in the active layer ACT, and the first and third active layers 130a and 130c on the lower and upper parts of the second active layer 130b, are relatively low-mobility active layers. For example, the mobility of the second active layer 130b can be 15 cm²/Vs or more, and the mobility of the first active layer 130a and the third active layer 130c can be 14 cm²/Vs or less.

The second active layer 130b can include metal having high conductivity, such as iron (Fe), zinc (Zn), or tin (Sn), as a metal component included for a relatively high mobility in the active layer ACT.

For example, the second active layer 130b can include at least one of FIZO (Fe—In—Zn-Oxide), ZnO (Zn-Oxide), and SnO (Sn-Oxide).

For example, when the first to third active layers 130a, 130b, and 130c each include IGZO (In—Ga—Zn-Oxide), content ratios thereof can be different, so that content ratios of the second active layer 130b can be different from content ratios of the first and third active layers 130a and 130c. In order to achieve a high mobility of the second active layer 130b when the first to third active layers 130a, 130b, and 130c each include IGZO (In—Ga—Zn-Oxide), the second active layer 130b can have an indium content ratio greater than a gallium content ratio (In>Ga), and the first active layer 130a and the third active layer 130c can have an indium content ratio less than or equal to a gallium content ratio (In≤Ga).

The doping region DP of the first and third active layers 130a and 130c of the transistor TFT1 according to the first embodiment of the present disclosure functions as a source-drain region, and can reduce resistance of a connection portion when connected to the first and second source-drain electrodes SD1 and SD2.

Meanwhile, the transistor TFT1 is arranged in one region of the substrate 111.

First and second interlayer insulating films 126 and 127 can be arranged between the first and second source-drain electrodes SD1 and SD2 and the gate electrode G. The first and second interlayer insulating films 126 and 127 can be provided as a single layer.

The gate insulating film 125 and the first and second interlayer insulating films 126 and 127 are arranged in sequence between the first and second source-drain electrodes SD1 and SD2 and the active layer ACT. The gate insulating film 125 and the first and second interlayer insulating films 126 and 127 have contact holes CTA and CTB that expose a part of the doping region DP of the third active layer 130c of the active layer ACT, so that the first source-drain electrode SD1 and the second source-drain electrode SD2 are connected to the active layer ACT through the contact holes CTA and CTB, respectively.

First to third insulating films 121, 122, and 123 can be arranged between the substrate 111 and the active layer ACT.

At least one of the first to third insulating films 121, 122, and 123 can function as a buffer layer to protect the substrate 111 and prevent impurities entering from the substrate 111 or the outside from penetrating into a component formed on the substrate 111.

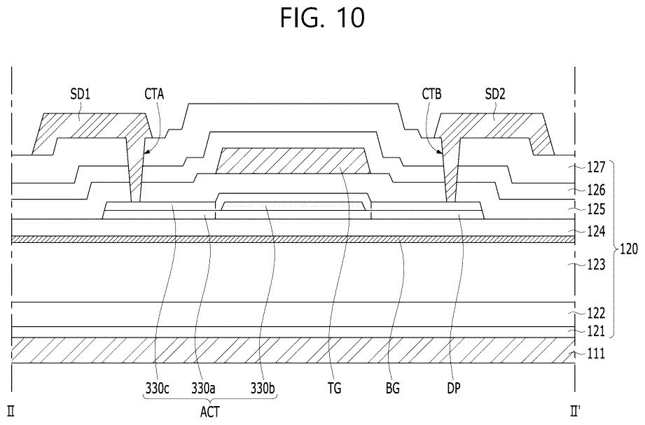

A lower side of the active layer ACT can further include a light-shielding pattern (see BG of FIG. 10) to prevent external light entering from the substrate 111 from affecting the active layer ACT. The light-shielding pattern can be arranged, for example, between the first insulating film 121 and the second insulating film 122, or between the second insulating film 122 and the third insulating film 123. Alternatively, when the third insulating film 123 is formed by stacking a plurality of insulating films, the light-shielding pattern can be formed in the third insulating film 123 by interposing at least one insulating film between the active layer ACT and the light-shielding pattern.

The first to third insulating films 121, 122, and 123, the gate insulating film 125, the first interlayer insulating film 126, and the second interlayer insulating film 127 can be part of an insulating film 120 formed on the substrate 111 and can be inorganic insulating films. For example, the inorganic insulating film can include one or more inorganic films of a silicon oxide (SiOx) film, a silicon nitride (SiNx) film, and a silicon oxynitride (SiOxNy) film. For example, in addition to silicon, another element component can be further included in one of an oxide film, a nitride film, and an oxynitride film to form the inorganic insulating film.

After the first and second source-drain electrodes SD1 and SD2 are arranged, an insulating film can be further provided to protect the transistor TFT1 and to planarize a surface of an upper part of the transistor TFT1, and the insulating film for planarization can be an organic insulating film.

When the active layer ACT is made of an oxide semiconductor, if the gate insulating film 125 and the third insulating film 123 adjacent to the active layer ACT are made of a silicon oxide film, the number of hydrogen particles emitted during a heat treatment step, etc. in a process is not large, so that it is possible to minimize a decrease in reliability of the active layer ACT adjacent to the third insulating film 123 and the gate insulating film 125 due to hydrogen particles during the process.

Meanwhile, the transistor TFT1 according to the first embodiment of the present disclosure mentioned above has been described as an example in which the active layer ACT includes the high-mobility second active layer 130b between the low-mobility first and third active layers 130a and 130c and is configured with a length ACL smaller than the length GTL of the gate electrode G to ensure an effective channel length.

Hereinafter, a conductive diffusion region according to a length of an active layer of high mobility in a structure including both low-mobility and high-mobility active layers will be examined with reference to experimental examples.

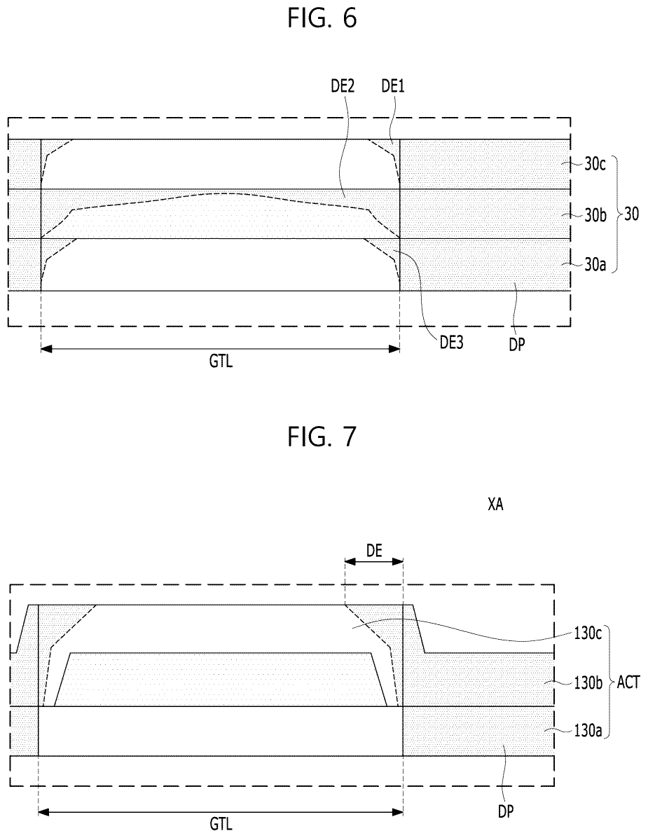

FIG. 6 is a cross-sectional view illustrating a conductive region in a multilayer configuration of an active layer of a transistor of a first experimental example. FIG. 7 is a cross-sectional view illustrating a conductive region in a multilayer configuration of an active layer of a transistor of a second experimental example.

The transistor according to the first experimental example EX1 of FIG. 6 includes an active layer 30 in which a first active layer 30a of low mobility, a second active layer 30b of high mobility, and a third active layer 30c of low mobility are sequentially stacked, and a gate electrode having the first length GTL is used as a mask to inject an impurity into the gate electrode and the non-overlapping active layer 30, thereby forming the doping region DP.

Here, the transistor of the first experimental example EX1 has the first to third active layers 30a, 30b, and 30c formed with the same length in a direction of the first length GTL, and in this case, the doping region DP is evenly generated in the first to third active layers 30a, 30b, and 30c located outside the gate electrode.

In addition, when such a transistor is operated, due to heat generation, impurities are diffused from the doping region DP to a region overlapping the gate electrode, and if a degree of diffusion is severe, as shown in FIG. 6, due to a difference in mobility between the first to third active layers 30a, 30b, and 30c, a degree of occurrence of a second conductive diffusion region DE2 in the second active layer 30b having a relatively high mobility can be greater than that of the first and third conductive diffusion regions DE1 and DE3 of the first active layer 30a and the third active layer 30c having a low mobility. In this case, the second conductive diffusion region DE2 in the second active layer 30b can penetrate into a center of the intrinsic region of the second active layer 30b, so that the second active layer 30b is substantially conductive, and the active layer 30 can lose a switching function for selective operation when a gate voltage is applied.

As shown in FIG. 7, the transistor according to the second experimental example EX2 is represented by a region XA of FIG. 5. The active layer ACT includes an active layer ACT in which a first active layer 130a having a low mobility, a second active layer 130b having a high mobility, and a third active layer 130c having a low mobility are sequentially stacked, and an upper surface and a side surface of the second active layer 130b are arranged to be surrounded by the third active layer 130c.

In addition, the third active layer 130c on the side surface of the second active layer 130b is in contact with the first active layer 130a located below, so that a lower part, a side part, and an upper part of the second active layer 130b are surrounded by the first active layer 130a and the third active layer 130c having a low mobility.

Therefore, conductive diffusion occurring at the boundary between the doping region DP and the non-doping region UDP mainly occurs in the low-mobility third active layer 130c located outside the second active layer 130b, and the second active layer 130b, which is an intrinsic region and functions as a channel, may not be affected by the conductive diffusion. Here, since the third active layer 130c and the first active layer 130a have a low mobility, a degree of occurrence of the conductive diffusion region can be smaller than that in the second conductive diffusion region DE2 in the second active layer 30b examined in the first experimental example EX1. In addition, since the second active layer 130b has different properties from those of the first and third active layers 130a and 130c and is located inside the boundary between the intrinsic region UDP and the doping region DP in the third active layer 130c, it is difficult for impurities to penetrate from the third active layer 130c and the first active layer 130a into the second active layer 130b.

Accordingly, the transistor according to the second experimental example EX2 can ensure an effective channel length at a level of the length ACL of the second active layer 130b without conductive diffusion of the second active layer 130b due to heat generation during operation, and has reliability in operating the transistor since the effective channel length does not change over time.

Hereinafter, a transistor according to a second embodiment of the present disclosure has a difference in a configuration of a gate insulating film from the transistor of the first embodiment.

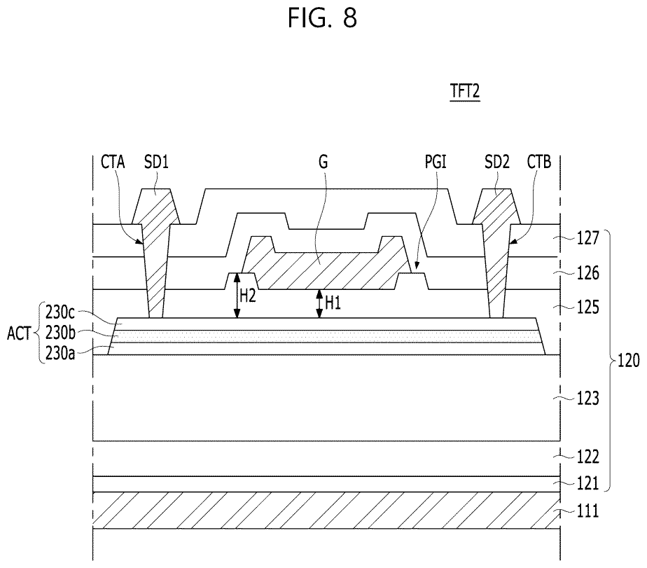

FIG. 8 is a cross-sectional view illustrating the transistor according to the second embodiment of the present disclosure.

As shown in FIG. 8, the transistor TFT2 according to the second embodiment of the present disclosure includes an active layer ACT including a first active layer 230a, a second active layer 230b, and a third active layer 230c that are sequentially stacked, a gate electrode G overlapping the active layer ACT, and a gate insulating film 125 between the active layer ACT and the gate electrode G, and among the first to third active layers 230a, 230b, and 230c provided in the active layer ACT, the second active layer 230b can have the highest mobility.

Here, the first to third active layers 230a, 230b, and 230c can be etched and formed in the same patterning process to have the same or similar width.

In addition, to prevent the conductive diffusion region of the second active layer 230b having a high mobility from being significantly generated, the transistor TFT2 according to the second embodiment is formed so that the gate insulating film 125 has a first thickness H1 in a region where the gate electrode G overlaps the active layer ACT, and the gate insulating film 125 is formed to have a second thickness H2 greater than the first thickness H1 in a region corresponding to an edge of the gate electrode G. In this way, doping concentration near the edge of the gate electrode G where conductive diffusion starts can be lowered, thereby preventing or minimizing conductive diffusion from occurring in a channel of the active layer ACT overlapping the gate electrode G.

There are differences in a length configuration of the second active layer 230b and a heterogeneous configuration of the gate insulating film 125, and other configurations are the same as those of the transistor according to the first embodiment. Description of the same configurations will be omitted.

Hereinafter, a description will be given of a configuration of a transistor having a wide width for high output according to aspects of the present disclosure.

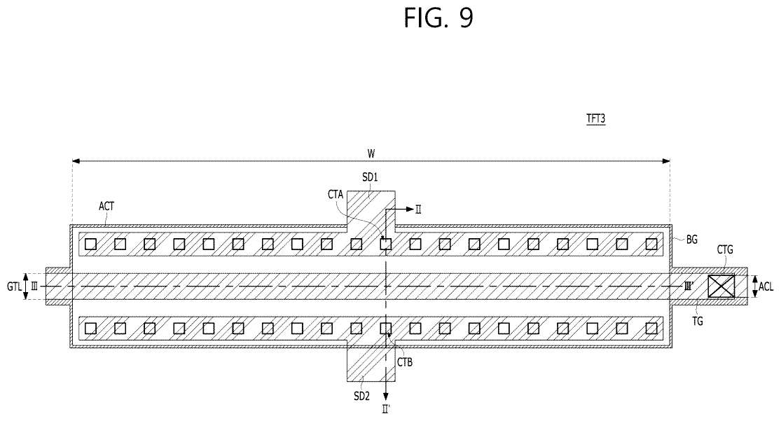

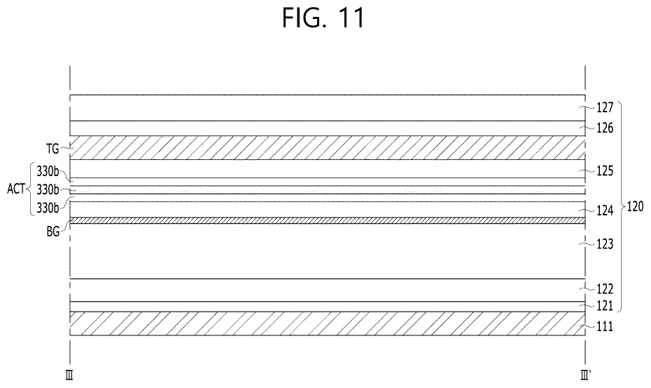

FIG. 9 is a plan view illustrating a transistor according to a third embodiment of the present disclosure, FIG. 10 is a cross-sectional view taken along line II-II′ of FIG. 9, and FIG. 11 is a cross-sectional view taken along line III-III′ of FIG. 9.

As shown in FIGS. 9 to 11, the transistor TFT3 according to the third embodiment of the present disclosure includes an active layer ACT including a first active layer 330a, a second active layer 330b, and a third active layer 330c that are sequentially stacked, a gate electrode TG overlapping the active layer ACT, and a gate insulating film 125 between the active layer ACT and the gate electrode TG. Here, among the first to third active layers 330a, 330b, and 330c provided in the active layer ACT, the second active layer 330b has the highest mobility, and an upper surface and a side surface of the second active layer 330b are protected by the third active layer 330c thereon, and a lower surface thereof is protected by the first active layer 330a.

The active layer ACT has a width W according to a direction of progression of the gate electrode TG and first and second source-drain electrodes SD1 and SD2. The first and second source-drain electrodes SD1 and SD2 are spaced apart from the gate electrode TG by a certain distance on a plane and are located outside the gate electrode TG, as shown in FIG. 9.

The first and second source-drain electrodes SD1 and SD2 are connected to the

active layer ACT in parallel with a width W direction of the active layer ACT. The first source-drain electrode SD1 has a plurality of first contact holes CTAs at positions spaced apart from the gate electrode TG by a certain distance and is connected to the active layer ACT through the first contact holes CTAs. The second source-drain electrode SD2 is provided with a plurality of second contact holes CTB at positions facing the first source-drain electrode SD1 with the gate electrode TG interposed therebetween, and is connected to the active layer ACT through the second contact holes CTB. The second source-drain electrode SD2 is spaced apart from the gate electrode TG by a certain distance.

The first source-drain electrode SD1 and the second source-drain electrode SD2 extend outside the active layer ACT and are connected to external wires or electrode patterns to receive electrical signals.

The lower part of the active layer ACT is further provided with a light-shielding pattern BG to prevent external light entering from the lower part of the substrate 111 from affecting the active layer ACT.

As shown in FIG. 9, the light-shielding pattern BG can extend to the outside the active layer ACT and be connected to the overlapping gate electrode TG through a third contact hole CTG. In this way, the gate electrode TG functions as a top gate, and the light-shielding pattern BG functions as a bottom gate, so that it is possible to function as a dual gate in the transistor TFT3. Since the light-shielding pattern BG is doped with impurities using the gate electrode TG as a mask, the doping region DP is provided in a region of the active layer ACT not overlapping with the gate electrode TG. The doping region DP of the active layer ACT and the first and second source-drain electrodes SD1, SD2 are connected to each other.

The light-shielding pattern BG is positioned below the active layer ACT and can be provided by interposing at least one insulating film 124.

The light-shielding pattern BG can be arranged below the active layer ACT with the fourth insulating film 124 interposed therebetween to be spaced apart therefrom, or can be positioned on top of any one of the first to fourth insulating films 121, 122, 123, and 124 located on the lower side of the active layer ACT in the insulating film 120 formed up to the first and second source-drain electrodes SD1 and SD2 on the substrate 111.

The transistor TFT3 according to the third embodiment of the present disclosure has the light-shielding pattern BG provided between the substrate 111 and the active layer ACT. The light-shielding pattern BG can be connected to the gate electrode TG in a region not overlapping with the active layer ACT.

In the transistor TFT3 according to the third embodiment of the present disclosure, the light-shielding pattern BG overlaps the second active layer 330b and can be provided with a larger area than that of the second active layer 330b. In the example illustrated in FIG. 9, the light-shielding pattern BG completely overlaps the active layer ACT and extends to the outside thereof to be connected to the gate electrode TG through the third contact hole CTG. However, the transistor according to the embodiment of the present disclosure is not limited thereto. The light-shielding pattern BG can be provided in a region including at least a channel region of the active layer ACT in a form overlapping the gate electrode TG to prevent external light entering from below the substrate 111 from affecting the channel of the active layer ACT to generate an off current.

The first to fourth insulating films 121, 122, 123, and 124 of the insulating film 120, the gate insulating film 125, the first interlayer insulating film 126, and the second interlayer insulating film 127 can each independently be an inorganic insulating film.

For example, the inorganic insulating film forming the insulating film 120 can include one or more inorganic films among a silicon oxide (SiOx) film, a silicon nitride (SiNx) film, and a silicon oxynitride (SiOxNy) film. For example, in addition to silicon, another element component can be further included in one of the oxide film, the nitride film, and the oxynitride film to form the inorganic insulating film.

Meanwhile, as shown in FIGS. 4 and 5, in the active layer ACT, an upper surface and a side surface of the second active layer 330b can be surrounded by the third active layer 330c in a longitudinal direction intersecting the width W direction of the active layer ACT, and the second active layer 330b can be protected by the third active layer 330c. Here, the third active layer 330c on the side surface of the second active layer 330b can be in contact with the first active layer 330a. In this case, the upper, side, and lower parts of the second active layer 330b are all low-mobility active layers, so that when the transistor is operated, diffusion of impurities due to heat generation is caused only in the first and third active layers 330a and 330c having a low mobility, thereby being able to reduce a degree of impurity diffusion. In addition, even when impurities diffuse in the active layer ACT, the second active layer 330b is arranged in the length GTL of the gate electrode TG with a length ACL shorter than the length GTL of the gate electrode TG, so that impurity diffusion can be prevented from penetrating into the high-mobility second active layer 330b due to the different characteristics and length difference between the low-mobility active layers 330a and 330c.

In the transistor TFT3 according to the third embodiment of the present disclosure, the gate electrode TG overlaps the active layer ACT over the entire width W, extends further to the outside of the active layer ACT, and is connected to the light-shielding pattern BG located in the lower part through the third contact hole CTG.

The second active layer 330b of the active layer ACT is arranged with a length ACL shorter than the length GTL of the gate electrode TG in the longitudinal direction, and at the time of doping with an impurity using the gate electrode TG, the impurity is not doped and the characteristics of the intrinsic region are maintained.

Therefore, when doping with an impurity using the gate electrode TG, the impurity is doped in a region of the first and third active layers 330a and 330c located outside the gate electrode TG, and a doping region is formed.

In addition, the transistor TFT3 according to the third embodiment of the present disclosure is provided with the wide active layer ACT, the first to third active layers 330a, 330b, and 330c can have the same width W, and the second active layer 330b is provided shorter than the first and third active layers 330a and 330c in the longitudinal direction of the active layer ACT. The second active layer 330b can have a length ACL shorter than the length GTL of the gate electrode TG. The first and third active layers 330a and 330c are longer than the length GTL of the gate electrode TG and have a width sufficient to overlap the first and second source-drain electrodes SD1 and SD2 on both sides of the gate electrode TG. Here, the total length of the first and third active layers 330a and 330c corresponds to the length of the active layer ACT, and the doping region of the impurity is located in the region of the first and third active layers 330a and 330c protruding from the gate electrode TG.

The transistor TFT3 according to the third embodiment of the present disclosure has a channel in the second active layer 330b having a high mobility in the active layer ACT having a plurality of layers including the low-mobility active layer 330a and 330c and the high-mobility active layer 330b, thereby improving mobility of the transistor TFT3.

When compared to conductive diffusion increasing at the time of operating the high-mobility active layer as a single layer, a structure in which the high-mobility second active layer 330b is protected by the low-mobility first and third active layers 330a and 330c can prevent impurity diffusion from occurring in the first and third active layers 330a and 330c and affecting the second active layer 330b, the second active layer 330b located inside the gate electrode TG can be maintained as an intrinsic region, and an effective channel length greater than or equal to a certain level can be ensured between the first and second source-drain electrodes SD1 and SD2, thereby improving reliability of the transistor.

By providing the high-mobility second active layer 330b inside the edge of the gate electrode TG, diffusion occurring from the boundary between the doping region and the non-doping region overlapping the edge of the gate electrode can be prevented from affecting the high-mobility second active layer 330b, thereby controlling the change in channel length in the wide-width transistor, and ensuring a channel length at least as long as the length ACL of the second active layer 330b, so that it is possible to increase reliability of the wide-width transistor.

The high-mobility second active layer 330b functions as a channel, so that charge flow can occur in the short channel length between the first and second source-drain electrodes SD1 and SD2 and on-state current can be increased. When a transistor including such a high-mobility active layer is configured as a driving transistor, luminance can be improved. When the channel length increases, a threshold voltage increases. However, the transistor according to the embodiments of the present disclosure has a short channel and thus can have a threshold voltage less than or equal to a certain level.

When the high-mobility second active layer 330b is covered with the low-mobility first and third active layers 330a and 330c above and below, the change in effective channel length is prevented, and the margin of the channel length can be reduced compared to a structure having a single-layer high-mobility active layer, so that the transistor can be implemented in a smaller size, which is advantageous for high-resolution applications. In other words, threshold voltage sensitivity of the high-mobility device can be reduced and the effective channel can be ensured at a certain level or more, thereby improving reliability of the device.

In addition, in the transistor TFT3, the gate electrode TG and the light-shielding pattern BG are connected to form a dual gate structure, thereby enabling high response speed, and the transistor TFT3 can be implemented in a smaller size, so that it is advantageous for high-resolution placement. In this case, it is advantageous for application to a device that is provided in a subpixel of an active area, such as a switching transistor, and requires high response speed.

When the transistor including the active layer ACT shown in FIGS. 9 to 11 is provided in the drive unit, the transistor can be implemented as a transistor having a short channel and a wide width, so that the display device can be implemented with a narrow bezel.

When the active layer ACT having the first to third active layers 330a, 330b, and 330c is included in a wide-width transistor that requires high output, the change in effective channel length is effectively prevented, and the channel length can be maintained at least at the level of the length ACL of the second active layer ACT, so that image quality can be improved through reduction of parasitic capacitance.

Meanwhile, the wide-width transistor according to the third embodiment of the present disclosure is advantageously applied to devices that have high response speed or require high output voltage or high output current, such as transistors in the GIP of the non-active area or switching transistors in the active area.

The transistor TFT3 according to the third embodiment of the present disclosure can be provided in either the active area AA or the non-active area NA.

The transistor TFT3 according to the third embodiment of the present disclosure can be provided in the non-active area to function as a wide-width transistor included in a drive unit integrated in the non-active area, or can function as a wide-width transistor for high output in the active area or as a switching transistor in terms of high response speed without threshold voltage change.

Hereinafter, the driving current change according to application of the gate voltage Vg will be examined for the transistors of the first to third experimental examples having different active layer configurations.

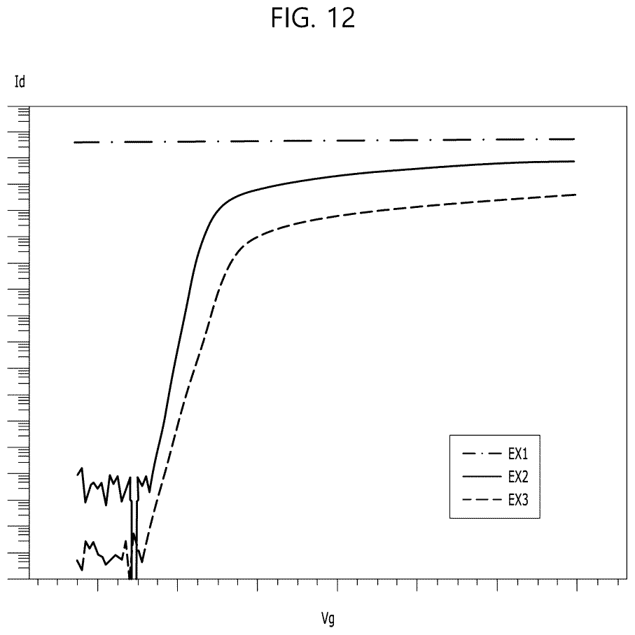

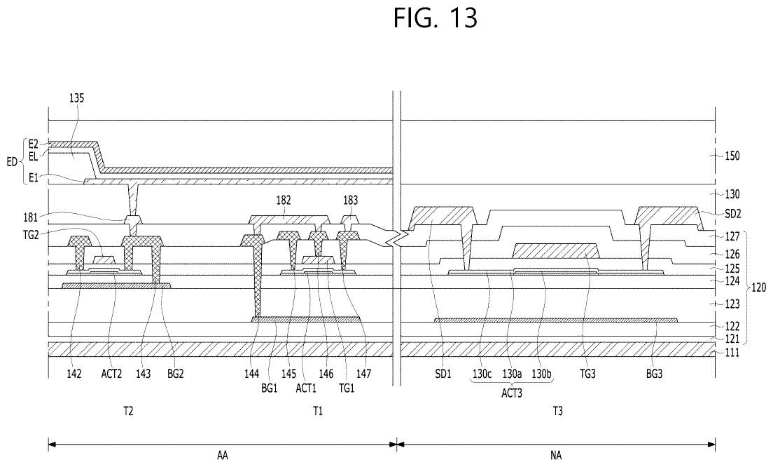

FIG. 12 is a graph illustrating I-V characteristics of the transistors of the first to third experimental examples.

Referring to FIG. 12, the first experimental example EX1 is related to the transistor according to the first experimental example illustrated in FIG. 6, which includes the active layer 30 in which the first active layer 30a having a low mobility, the second active layer 30b having a high mobility, and the third active layer 30c having a low mobility are stacked, and the first to third active layers 30a, 30b, and 30c are patterned in the same etching process and have the same or similar widths.

The second experimental example EX2 is related to the transistor of the second experimental example according to FIG. 7 and FIGS. 4 and 5, in which the active layer ACT is formed by stacking the first active layer 130a with a low mobility, the second active layer 130b having a high mobility, and the third active layer 130c having a low mobility, and the second active layer 130b overlaps the gate electrode G and is arranged inside the edge of the gate electrode G.

The third experimental example EX3 is related to the transistor including a single active layer having a low mobility, and the active layer ACT is formed as a single low mobility active layer.

In the experiment, the mobility of the low-mobility active layer in the first to third experimental examples EX1, EX2, and EX3 of FIG. 12 was set to 10 cm²/Vs, and the mobility of the high-mobility active layer was set to 20 to 50 cm²/Vs.

In the transistor according to the first experimental example EX1, the active layer 30 is formed by stacking the first active layer 30a having a low mobility/the second active layer 30b having a high mobility/the third active layer 30c having a low mobility. However, when diffusion occurs due to heat generated at the time of operating the transistor, the first to third active layers 30a, 30b, and 30c having the same or similar lengths can simultaneously undergo impurity diffusion, and a degree of diffusion can be particularly large in the second active layer 30b having a high mobility. Accordingly, impurity diffusion can occur to a center of the channel, and the entire channel can become conductive. For example, the effective channel length can approach 0. In this case, as shown in FIG. 12, the transistor according to the first experimental example EX1 can confirm that a constant current Id flows even when the active layer 30 is conductive and loses the switching function and the gate voltage Vg is varied.

On the other hand, as shown in FIG. 12, when the second active layer 130b having a high mobility is arranged to be shorter than the length GTL of the gate electrode TG, the transistor according to the second experimental example EX2 maintains the characteristic of switching when the gate voltage Vg becomes a constant voltage or higher since a conductive diffusion region DE is generated in the first and third active layers 130a and 130c, and impurities do not reach the second active layer 130b even when diffusion occurs.

In addition, it can be confirmed that, compared to the transistor according to the second experimental example EX2, the third transistor EX3 having a relatively low mobility maintains the switching characteristics since the transistor has a low mobility and a degree of occurrence of the conductive diffusion region is small, but the magnitude of the driving current increasing as the gate voltage Vg increases is small. This means that the transistor having a low mobility has a small on-state current value, and that there is a limit to the extent to which the on-state current magnitude increases even when the gate voltage size is increased.

Comparatively, it can be confirmed that the second experimental example EX2 according to the embodiment(s) of the present disclosure has an on-state current value that increases compared to the third experimental example EX3 when the gate voltage increases.

Results of the transistor according to the second experimental example EX2 can be obtained in the same manner from the transistor according to the first embodiment of FIGS. 4 and 5 and the transistor according to the third embodiment.

According to the above experiments, the transistor according to the embodiments of the present disclosure can increase the on-state current by causing charge flow in the short channel length between the first and second source-drain electrodes SD1 and SD2 by using the high-mobility second active layers 130b and 330b as a channel, and when the transistor including such a high-mobility active layer is configured as a driving transistor, improvement in luminance can be expected.

When the high-mobility second active layers 130b and 330b are covered with the low-mobility first and third active layers 130a, 130c, or 330a, 330c on top and bottom, the change in effective channel length is prevented, and the margin of the channel length can be reduced compared to a structure having a single-layer high-mobility active layer, so that the transistor can be implemented in a smaller size, which is advantageous for high-resolution application. In particular, the transistor be applied as a transistor that improves reliability of the device by ensuring an effective channel at a constant level in a high-resolution structure where subpixels are gradually decreasing.

When a transistor including an active layer ACT is included in the drive unit, the transistor be implemented as a transistor having a short channel and a wide width, so that a display device can be implemented with a narrow bezel.

The transistor having the structure of the active layer according to the embodiments of the present disclosure described above can be applied as a transistor of a subpixel or a transistor of a drive unit.

When the transistor having the structure of the active layer according to the embodiments of the present disclosure described above is applied to the GIP, the light-shielding pattern located on the lower side of the active layer can be connected to the gate electrode to have the same potential and driven as a dual gate. In this case, the on-current characteristics can be improved. Further, since the gate voltage is applied doubly through the light-shielding pattern and the gate electrode, the area of the transistor can be reduced, and narrow bezel implementation is easy. In addition, when an oxide semiconductor is used, narrow bezel implementation is easier, and productivity can be improved.

The light-shielding pattern is arranged in a size greater than that of the active layer, so that the active layer located on top can be flattened.

The transistor of the GIP also forms the active layer using the oxide semiconductor, similarly to the transistor in the active area AA, so that process optimization is possible.

In addition, when providing the first to third active layers of the active layer, a structure in which all of the active layers include oxide semiconductors is possible. Further, since the transistor can be operated using high mobility characteristics of the second active layer, when compared to the single-layer active layer requiring a certain length margin or more, this margin can be omitted or reduced, and it is advantageous for application to transistors in a high-resolution display device. In addition, low-power operation is possible by increasing mobility of the transistor.

In providing the first to third active layers of the active layer, a structure in which all of the active layers include oxide semiconductors is possible. Further, since a high-temperature crystallization process is omitted for heterogeneous transistors provided in the display device, there is an advantage in that greenhouse gases can be reduced. Further, since there is an environmental and social sustainability advantage, ESG (Environmental/Social/Governance) goals can be achieved.

Hereinafter, a display device according to one or more embodiments of the present disclosure will be examined.

FIG. 13 is a cross-sectional view illustrating the display device according to the embodiment of the present disclosure.

Referring to FIG. 13, the substrate 111 includes an active area AA and a non-active area NA.

The active area AA is an area where the subpixel SP described in FIG. 1 is arranged, and the drive unit such as the GIP is arranged in the non-active area NA.

The substrate 111 can be formed of a flexible plastic material and can have flexible characteristics. For example, the substrate 111 can include first and second organic films that overlap each other with an inorganic interlayer insulating film therebetween. The first and second organic films can include different organic films of the same or different types, such as PET (polyethylene terephthalate) and polyimide. In some cases, an adhesive film such as a PSA (pressure sensitive adhesive) can be included between the first and second organic films.

As another example, the substrate 111 can include a flexible and thin glass material.

The substrate 111 serves to support and protect components of the display device 1000 arranged thereon.

The active area AA of the substrate 111 can include the first transistor T1 connected to the gate line (GL of FIG. 1) and the data line (DL in FIG. 1), and the second transistor T2 electrically connected to the light emitting element ED. The first and second transistors T1 and T2 can have a direct connection relationship with each other, and in some cases, can be connected in a partial configuration of the compensation circuit included therebetween. The first transistor T1 can be, for example, a switching transistor, and the second transistor T2 can be, for example, a driving transistor.

The non-active area NA of the substrate 111 can include the third transistor T3. For example, the third transistor T3 can be included in the GIP, and can be a buffer transistor having high output. When the third transistor T3 is included in the GIP, the third transistor T3 can have an electrical connection relationship with the gate line GL and supply a gate voltage signal.

A plurality of insulating films 120 (121, 122, 123, 124, 125, 126, and 127) is stacked in the active area AA and the non-active area NA of the substrate 111 so that electrodes BG1, BG2, BG3, TG1, TG2, TG3, 146, 147, 142, 143, and SD2 and active layers ACT1, ACT2, and ACT3 included in the first to third transistors T1, T2, and T3 can be insulated from each other. The insulating film 120 can include, for example, the first insulating film 121, the second insulating film 122, the third insulating film 123, the fourth insulating film 124, the gate insulating film 125, the first interlayer insulating film 126, and the second interlayer insulating film 127.

In addition to the first to third transistors T1, T2, and T3 shown in part of the active area AA or the non-active area NA of the substrate 111, a transistor having an active layer provided in another layer can be further provided. At least one of the first to fourth insulating films 121, 122, 123, and 124 can function as a buffer layer or an interlayer insulating film of an active layer other than the active layers ACT1, ACT2, and ACT3 of the first to third transistors T1, T2, and T3, for example, an active layer including polysilicon.

The first insulating film 121 is disposed in the active area AA and the non-active area NA on the substrate 111. The first insulating film 121 can be referred to as a buffer layer and can perform the same function as that of a buffer layer known in the art. The first insulating film 121 can be disposed on the substrate 111 to protect structures located in an upper part of the substrate 111 from moisture penetrating through the substrate 111 and can flatten a surface of the substrate 111.

The first insulating film 121 can be disposed up to an edge of the substrate 111 to prevent moisture from penetrating from the edge of the substrate 111. The first insulating film 121 can be a single inorganic film or can include a plurality of inorganic films that are alternately stacked.

For example, the first insulating film 121 can include one or more inorganic films among a silicon oxide (SiOx) film, a silicon nitride (SiNx) film, and a silicon oxynitride (SiOxNy) film, or can include a multilayer in which the inorganic films described above are stacked.

The second insulating film 122 can be disposed on the first insulating film 121. The second insulating film 122 can function as, for example, a second buffer layer. In this case, some of the transistors included in the subpixel can include a polysilicon semiconductor layer, and the second insulating film 122 can be positioned in a lower part of the polysilicon semiconductor layer. The second insulating film 122 can include an inorganic film, for example, a silicon oxide (SiOx) film, a silicon nitride (SiNx) film, or a multilayer thereof. The second insulating film 122 can be used as a gate insulating film of a transistor including the polysilicon semiconductor layer, depending on the case.

A first light-shielding pattern BG1 in the active area AA and a third light-shielding pattern BG3 in the non-active area NA can be provided on the second insulating film 122 using a conductive metal material. The first and third light-shielding patterns BG1 and BG3 and, specifically, the conductive metal material can include at least one of an aluminum series metal such as aluminum (Al) or an aluminum alloy, a silver series metal such as silver (Ag) or a silver alloy, a copper series metal such as copper (Cu) or a copper alloy, a molybdenum series metal such as molybdenum (Mo) or a molybdenum alloy, chromium (Cr), tantalum (Ta), neodymium (Nd), and titanium (Ti).

The first light-shielding pattern BG1 can form one electrode of a storage capacitor included in a subpixel.

The third insulating film 123 can be disposed on the second insulating film 122 where the first and third light-shielding patterns BG1 and BG3 are disposed. The third insulating film 123 can function as an insulator of a storage capacitor connected to at least one of the first to third transistors T1, T2, and T3. Alternatively, the third insulating film 123 can function as an interlayer insulating film of a transistor including a polysilicon semiconductor layer.

The third insulating film 123 can include an inorganic material. The inorganic material can include, for example, a silicon nitride (SiNx) film.

The second light-shielding pattern BG2 in the active area AA may be provided on the third insulating film 123 as a conductive metal material. Specifically, the conductive metal material can include at least one of an aluminum series metal such as aluminum (Al) or an aluminum alloy, a silver series metal such as silver (Ag) or a silver alloy, a copper series metal such as copper (Cu) or a copper alloy, a molybdenum series metal such as molybdenum (Mo) or a molybdenum alloy, chromium (Cr), tantalum (Ta), neodymium (Nd), and titanium (Ti).

The first light-shielding pattern BG1 and the second light-shielding pattern BG2 can be the same layers as the first electrode and the second electrode of the storage capacitor or the capacitor, respectively.

The first to third light-shielding patterns BG1, BG2, and BG3 can be a single layer or can have a stacked structure of a plurality of different metal materials.

The fourth insulating film 124 can be arranged on the third insulating film 123 equipped with the second light-shielding pattern BG2. The fourth insulating film 124 is positioned below the first to third active layer patterns ACT1, ACT2, and ACT3 and can function as a buffer layer. The fourth insulating film 124 can serve to flatten a surface of an area where the first to third active layer patterns ACT1, ACT2, and ACT3 arranged on the upper side are formed.

The fourth insulating film 124 can include an inorganic material. The inorganic material can include, for example, a silicon oxide (SiOx) film or a multilayer film in which inorganic films are stacked.

The first to third active layer patterns ACT1, ACT2, and ACT3 are arranged on the fourth insulating film 124. The first to third active layer patterns ACT1, ACT2, and ACT3 include, for example, an oxide semiconductor material. Further, as shown in FIGS. 4 and 5, the active layer patterns include the first active layer 130a having a low mobility, the second active layer 130b having a high mobility, and the third active layer 130c having a low mobility, and the length ACL of the second active layer 130b is formed shorter than the length GTL of the subsequently formed gate electrodes TG1, TG2, and TG3 in the longitudinal direction of the active layers (from the source electrode to the drain electrode).

Here, the first to third active layers 130a, 130b, and 130c can include an oxide semiconductor material. The oxide semiconductor material can be formed of a combination of an oxygen and at least one metal among zinc (Zn), indium (In), gallium (Ga), tin (Sn), and titanium (Ti). In some cases, the second active layer 130b can further include a metal having high conductivity, such as iron (Fe), in the oxide semiconductor material to increase mobility.

The example illustrated in FIG. 13 shows an example in which the first to third active layer patterns ACT1, ACT2, and ACT3 are provided in the same layer. In this case, a common active layer pattern formation process can be applied to the transistors provided in the display device 1000, there is an advantage of process optimization by not requiring a high-temperature crystallization process, and the high-temperature process can be omitted, thereby reducing greenhouse gas emissions. In addition, when the high-mobility second active layer 130b is used for each of the first to third active layer patterns ACT1, ACT2, and ACT3, the transistors have the operation characteristics of the mobility of the second active layer 130b and can be implemented as high-mobility transistors, and there is an effect of improving the on-state current. The embodiments of the present disclosure are not limited thereto. At least one of the active layer patterns ACT1, ACT2, and ACT3 included in the first to third transistors T forms an active layer having the above-described structure, and can have effects of improving on-state current, reducing effective channel length change, detecting threshold voltage variation, and increasing the width of the transistors.

In an embodiment of the present disclosure, the mobility of at least one of the first to third active layer patterns ACT1, ACT2, and ACT3 can be changed to correspond to a response speed of each transistor. For example, in the third transistor T3 in the non-active area NA and the first transistor T1 in the active area AA, the mobilities of the third active layer pattern ACT3 and the first active layer pattern ACT1 can be higher than the mobility of the second active layer pattern ACT2. The second transistor T2 in the active area AA may have a different structure from the first transistor T1 in the active AA and the third transistor T3 in the non-active area NA.

More specifically, the first to third active layer patterns ACT1, ACT2, and ACT3 can have different oxide semiconductor material content ratios between the first and third active layers 130a and 130c and the second active layer 130b. The first to third active layer patterns ACT1, ACT2, and ACT3 can have different widths and different lengths of overlap with the gate electrodes TG1, TG2, and TG3 for different characteristics, and the lengths of the second active layers 130b in the first to third active layer patterns ACT1, ACT2, and ACT3 can be differently applied.

The gate insulating film 125 is arranged to cover the first to third active layer patterns ACT1, ACT2, and ACT3.

On the gate insulating film 125, the active layer ACT, the first to third active layer patterns ACT1, ACT2, and ACT3 and the first to third gate electrodes TG1, TG2, and TG3 partially overlapping each other are arranged. The first to third gate electrodes TG1, TG2, and TG3 can include at least one of an aluminum-based metal such as aluminum (Al) or an aluminum alloy, a copper-based metal such as copper (Cu) or a copper alloy, a molybdenum-based metal such as molybdenum (Mo) or a molybdenum alloy, chromium (Cr), tantalum (Ta), neodymium (Nd), and titanium (Ti). The first to third gate electrodes TG1, TG2, and TG3 can be formed of a single layer or multiple layers.

The first gate electrode TG1 can be connected to, for example, the gate line G1 described in FIG. 1. In some cases, the gate line G1 and the first gate electrode TG1 can be integrally formed.

After the first to third gate electrodes TG1, TG2, TG3 are formed, the first active layer pattern ACT1, the second active layer pattern ACT2, and the third active layer pattern ACT3 are doped with impurities using the first to third gate electrodes TG1, TG2, TG3 as masks to form doping regions. The impurities can be, for example, ions of boron, phosphorus, and fluorine. The first active layer pattern ACT1, the second active layer pattern ACT2, and the third active layer pattern ACT3 overlap the first to third gate electrodes TG1, TG2, and TG3, respectively, and each have a channel in the second active layer 130b located inside, and can each have a doping region doped with impurities in a region outside the first to third gate electrodes TG1, TG2, and TG3, that is, in a region of the first and third active layers 130a and 130c.

The first interlayer insulating film 126 is disposed on the gate insulating film 125 where the first to third gate electrodes TG1, TG2, and TG3 are disposed.

The first interlayer insulating film 126 and the gate insulating film 125 in the insulating film 120 are selectively removed to form a contact hole through which the doping regions of the first and second active layer patterns ACT1 and ACT2 are exposed, the first interlayer insulating film 126, the gate insulating film 125, and the fourth insulating film 124 are selectively removed in outer part of the second active layer pattern ACT2 to form a contact hole through which a partial upper part of the second light-shielding pattern BG2 is exposed, and the first interlayer insulating film 126, the gate insulating film 125, the fourth insulating film 124, and the third insulating film 123 are selectively removed in a partial outer part of the first light-shielding pattern BG1 and/or the third light-shielding pattern BG3 to expose a partial upper part of the first active layer pattern ACT1 and/or the third active layer pattern ACT3. In the same process, the first interlayer insulating film 126 is removed to form a contact hole exposing a partial upper part of the first gate electrode TG1 of the first transistor T1.

Then, a metal material is formed on the first interlayer insulating film 126 to fill each contact hole, the metal material is selectively removed to form the first and second source-drain electrodes 145 and 147 of the first transistor Tl connected to both sides of the first active layer pattern ACT1, and the first connection pattern 146 connected to a partial upper part of the first gate electrode TG1 and the second connection pattern 144 connected to the first light-shielding pattern BG1 on the outside of the first active layer pattern ACT1 are formed. In addition, the first and second source-drain electrodes 141 and 143 of the second transistor T2 connected to both sides of the second active layer pattern ACT2 are formed. The second source-drain electrode 143 is extended so that one side thereof is outside the second active layer pattern ACT2 and connected to the second light-shielding pattern BG2.

The second interlayer insulating film 127 is arranged on the first interlayer insulating film 126 where the first and second source-drain electrodes 145, 147, 142, and 143 of the first and second transistors T1 and T2 and the first and second connection patterns 146 and 144 are formed.

The second interlayer insulating film 127 is selectively removed to form a contact hole exposing a partial upper part of the second source-drain electrode 143 of the second transistor T2 and a contact hole exposing a partial upper part of the first and second connection patterns 146 and 144, and the second interlayer insulating film 127, the first interlayer insulating film 126, and the gate insulating film 125 are selectively removed to form a contact hole exposing both sides of the third active layer pattern ACT3 of the third transistor T3.

The contact holes are filled with a metal material formed on the second interlayer insulating film 127 and patterned to form a first connection pattern 181 connected to the second source-drain electrode 143 of the second transistor T2, a second connection pattern 182 connected with the first and second connection patterns 146 and 144, a third connection pattern 183 connected to the second source-drain electrode 147 of the first transistor T1, and the first and second source-drain electrodes SD1 and SD2 connected to both sides of the third active layer pattern ACT3 of the third transistor T3.

The third connection pattern 183 can be connected to the data line DL described in FIGS. 1 and 2.

In the illustrated example, the first and second source-drain electrodes SD1 and SD2 are formed on the second interlayer insulating film 127. However, the embodiment of the present disclosure is not limited thereto, and the first and second source-drain electrodes SD1 and SD2 of the third transistor T3 can be formed on the first interlayer insulating film 126 similarly to the first transistor T1 and the second transistor T2.

The first interlayer insulating film 126 and the second interlayer insulating film 127 are formed of an inorganic insulating material, and can be a single layer in some cases.

The first interlayer insulating film 126 and the second interlayer insulating film 127 can include, for example, a silicon oxide (SiOx) film, a silicon nitride (SiNx) film, or a multilayer film in which inorganic films are stacked.

A planarization film 130 can be provided on the second interlayer insulating film 127 where the first to third connection patterns 181, 182, and 183 and the first and second source-drain electrodes SD1 and SD2 of the third transistor T3 are formed, so as to planarize the surface on which the light emitting element ED is formed.

The planarization film 130 can include an organic material. The organic material can include one or more of an acrylic resin, a phenolic resin, a polyimide resin, an unsaturated polyester resin, a polyamide resin, benzocyclobutene, a polyphenylene resin, and a polyphenylene sulfide resin.

An anode E1 is further provided on the planarization film 130 and can be connected to a first connection pattern 181 through a contact hole in the planarization film 130.

An anode E1, a cathode E2 facing the anode E1, and an intermediate layer EL2 between the anode E1 and the cathode E2 form a light emitting element ED.

One of the anode E1 and the cathode E2 can include a reflective electrode, and the other can include a transparent electrode or a reflective-transparent electrode.

When the anode E1 includes a reflective electrode, the anode E1 can function to shield light from being incident on the first and second transistors T1 and T2 of the lower part. The anode E1 can be formed of, for example, a stacked structure of a first transparent electrode, a reflective electrode, and a second transparent electrode. The second transparent electrode, which is an uppermost electrode of the anode E1, can lower a barrier for hole injection at an interface with the intermediate layer EL as a dielectric. Here, the first and second transparent electrodes can be transparent oxide electrodes such as ITO and IZO. The reflective electrode can include silver, a silver alloy such as APC (Ag—Pd—Cu), aluminum, or an aluminum alloy.

For example, the anode (E1) can be formed of a multilayer structure such as a stacked structure (Ti/Al/Ti) of aluminum (Al) and titanium (Ti), a stacked structure (ITO/Al/ITO) of aluminum (Al) and ITO, an APC (Ag/Pd/Cu) alloy, a stacked structure (ITO/APC/ITO) of an APC alloy and ITO, and a stacked structure (Ag/MoTI) of silver (Ag) and an molybdenum/titanium alloy, or can include a single layer structure made of one material selected from silver (Ag), aluminum (Al), molybdenum (Mo), gold (Au), magnesium (Mg), calcium (Ca), barium (Ba), and an alloy of two or more thereof.

A pixel defining film 135 can be arranged to surround the edge of the anode E1, and a light emitting portion can be defined in an open area of the pixel defining film 135. The pixel defining film 135 can extend to the non-active area NA and can have a region at least partially overlapping with the GIP.

The pixel defining film 135 can include an inorganic material or an organic material. The pixel defining film 135 can include an opaque material (for example, black) to prevent optical interference between adjacent subpixels SP. In this case, the pixel defining film 135 can include a light-shielding material made of at least one of a color pigment, organic black, and carbon.

The intermediate layer EL can include a hole injection layer, a hole transport layer, a light emitting layer, an electron transport layer, an electron injection layer, etc. The intermediate layer EL can be formed by configuring a plurality of stacks including the hole transport layer, the light emitting layer, and the electron transport layer, and can be formed in a tandem structure including a charge generation layer between the stacks. The charge generation layer can include, for example, an n-type charge generation layer and a p-type charge generation layer.

The light emitting layer included in the intermediate layer EL can be provided differently for each subpixel. The light emitting layer EL can include a red light emitting layer that emits red light, a green light emitting layer that emits green light, and a blue light emitting layer that emits blue light. The red light emitting layer, the green light emitting layer, and the blue light emitting layer can be arranged for each subpixel SP on the anode E1.

For example, a red light emitting layer can be patterned and arranged for a red subpixel, a green light emitting layer can be patterned and arranged for a green subpixel, and a blue light emitting layer can be patterned and arranged for a blue subpixel. The present disclosure is not necessarily limited thereto, and at least two or more organic light emitting layers among the red light emitting layer, the green light emitting layer, and the blue light emitting layer can be stacked and arranged for one subpixel SP.

In some cases, the light emitting layer can be a white light emitting layer that emits white light. In this case, the light emitting layer EL can be in the form of a common layer in which one or more layers are commonly arranged in the subpixels SPs rather than in a patterned form.

As described above, the intermediate layer EL can be arranged in a tandem structure of two or more stacks STACK. In this instance, each light emitting element ED5 can include a charge generation layer arranged between the stacks. The charge generation layer can be a common layer arranged on the entire surface of the active area AA.

The cathode E2 can be formed by thinning a transparent electrode such as ITO or IZO, or a reflective transparent electrode such as silver, a silver alloy, magnesium, a magnesium alloy, ytterbium (Yb), or an ytterbium alloy. In another embodiment, in order to increase transmittance in a transmission portion TA, the cathode E2 can be partially removed from a region of the transmission portion TA or formed with a thin thickness. The cathode E2 can be a common layer commonly arranged across the subpixels SP and applies the same voltage. To this end, the cathode E2 can be arranged to extend from the active area AA to a part of the non-active area NA.

The cathode E2 can be a light-transmitting electrode. The cathode E2 can include a transparent conductive material (TCO) such as ITO or IZO that can transmit light, or a semi-transmissive conductive material such as magnesium (Mg), silver (Ag), or an alloy of magnesium (Mg) and silver (Ag). When the cathode E2 is formed of a semi-transmissive conductive material, light emitting efficiency can be increased by a micro cavity.

In the above description, a front emitting type light emitting element ED has been described as an example. However, the light emitting element ED of the present disclosure is not limited thereto, and can be a back emitting type light emitting element ED in which light emitted from the intermediate layer EL2 is emitted toward the substrate 111. In this case, the anode E1 can include a transparent or translucent electrode material, and the cathode E2 can include a reflective electrode material.

A capping layer is further formed on the cathode E2 to protect the cathode E2 of the light emitting element ED and increase upward light emission efficiency.

A sealing layer 150 is arranged on the light emitting element ED. The sealing layer 150 can cover the active area AA and the non-active area NA to prevent oxygen or moisture from penetrating into the light emitting element ED. Other layers, such as a capping layer, can be interposed between the sealing layer 150 and the cathode E2 as needed.

The sealing layer 150 can include a plurality of layers. The sealing layer 150 can be formed to have a structure in which an inorganic film including an inorganic insulating material and an organic film including an organic insulating material are alternately stacked. For example, the inorganic insulating material can include one or more materials among silicon oxide, silicon nitride, and/or silicon oxynitride.

The organic insulating material can include one or more materials selected from the group consisting of polyethylene terephthalate, polyethylene naphthalate, polycarbonate, polyimide, polyethylene sulfonate, polyoxymethylene, polyarylate, and hexamethyldisiloxane.

The first to third active layer patterns ACT1, ACT2, and ACT3 of FIG. 13 are illustrated as the configurations of FIGS. 4 and 5. However, the embodiment of the present disclosure is not limited thereto. As shown in FIG. 8, the gate insulating film 125 can be formed thicker at regions corresponding to the edges of the gate electrodes TG1, TG2, and TG3 than other regions, thereby lowering the impurity doping concentration at the edges of the gate electrodes TG1, TG2, and TG3, so that it is possible to prevent or minimize penetration of the conductive region occurring inside the gate electrodes TG1, TG2, and TG3. In addition, the first to third active layer patterns ACT1, ACT2, and ACT3 can have the same effect due to the same configuration of stacked layers as that of the active layers (ACT: 330a, 330b, and 330c) according to the third embodiment with reference to FIGS. 9 to 11.

The transistor according to the embodiment of the present disclosure allows the high-mobility second active layer 130b to function as a channel in the first to third active layer patterns ACT1, ACT2, and ACT3 so that charge flow occurs in a short channel length between the first and second source-drain electrodes, and on-state current can be increased. Accordingly, when a three-layer structure of active layers 130a, 130b, and 130c having a length difference including a high-mobility active layer is configured as the second active layer pattern ACT2, like the second transistor T2, luminance can be improved by improving the on-state current.

When the high-mobility second active layer 130b is covered with the low-mobility first and third active layers 130a and 330c on top and bottom, the first to third active layer patterns ACT1, ACT2, and ACT3 can prevent the change in effective channel length, and reduce the margin of the channel length compared to a structure having a single-layer high-mobility active layer, so that the transistor can be implemented in a smaller size. Therefore, since a constant effective channel can be ensured in a high-resolution structure in which subpixels become increasingly smaller, the first and second transistors T1 and T2 can be applied as transistors that improve reliability of the device. For example, not only the transistor T3 provided in the GIP, but also the first transistor T1 functioning as a switching transistor and the second transistor T2 functioning as a driving transistor have multilayer structures, and reliability of the device can be improved by providing a structure that protects the high-mobility second active layer ACT2.

When a transistor including an active layer ACT is included in a drive unit, a stable short-channel wide-width transistor can be implemented by preventing or minimizing the change in effective channel length in a transistor having a short channel and a wide width, so that the display device can be implemented with a narrow bezel.

The transistor having the structure of the active layer according to the embodiments of the present disclosure described above can be applied to a transistor of the subpixel or any transistor of the drive unit. In addition, the transistors can be manufactured in a common oxide semiconductor formation process, so that process optimization is possible while resolving multiple heat treatments required when providing transistors having different characteristics, the use of semiconductor layer materials, and yield reduction due to the use of masks.

The transistor having the structure of the active layer according to the embodiments of the present disclosure described above can increase the mobility of the active layer including the oxide semiconductor layer, and when compared to the single-layer active layer requiring a certain length margin or more, this margin can be omitted or reduced, and it is advantageous for application to transistors in a high-resolution display device.

In addition, when the transistor according to the embodiments of the present disclosure is applied to a wide-width transistor provided in the non-active area or the active area, width sensitivity of the active layer can be alleviated, so that a design freedom of a high-output transistor can be improved.

In providing the first to third active layers of the active layer, a structure in which all of the active layers include oxide semiconductors is possible. Further, since a high-temperature crystallization process is omitted for heterogeneous transistors provided in the display device, there is an advantage in that greenhouse gas emissions can be reduced. Further, since there is an environmental and social sustainability advantage, ESG (Environmental/Social/Governance) goals can be achieved.

The transistor and the display device according to the embodiments of the present disclosure have the following effects.

In a multilayer active layer including a low-mobility active layer and a high-mobility active layer, a channel is provided in the high-mobility active layer, thereby improving the mobility of the transistor.

Conductor diffusion during operation in a single-layer high-mobility active layer can be prevented by a structure that protects the high-mobility active layer using the low-mobility active layer, and reliability of the transistor can be improved by ensuring an effective channel length of a certain level or more.

When the high-mobility active layer is included in the active layer, the on-state current can be increased, and when a transistor including such a high-mobility active layer is configured as a driving transistor, luminance can be improved.

When the high-mobility active layer is provided inside the edge of the gate electrode, diffusion occurring from the boundary between the doping region and the non-doping region overlapping the edge of the gate electrode can be prevented from affecting the high-mobility active layer, thereby improving reliability of the wide-width transistor.

When the high-mobility active layer is covered with the low-mobility active layer on top and bottom, it is possible to implement a short-length channel in the high-mobility active layer. In addition, it is possible to achieve high response speed by using a dual-gate structure, and it is advantageous to arrange the transistors in a small size for high resolution.

When the transistor including the high-mobility active layer is included in the drive unit, a smaller size can be implemented, so that the display device can be implemented with a narrow bezel.

A transistor according to one embodiment of the present disclosure can comprise an active layer comprising a first active layer, a second active layer, and a third active layer that are sequentially stacked, a gate electrode overlapping the active layer and a gate insulating film between the active layer and the gate electrode. The second active layer can have a highest mobility among layers of the active layer.

In a transistor according to one embodiment of the present disclosure, each of the first to third active layers can include an oxide semiconductor including one or more metals.

In a transistor according to one embodiment of the present disclosure, the second active layer can include at least one of FIZO (Fe—In—Zn-Oxide), ZnO (Zn-Oxide), and SnO (Sn-Oxide).

In a transistor according to one embodiment of the present disclosure, each of the first to third active layers can include IGZO (In—Ga—Zn-Oxide). The second active layer can have an indium content ratio greater than a gallium content ratio. The first active layer and the third active layer can have an indium content ratio less than or equal to a gallium content ratio.

In a transistor according to one embodiment of the present disclosure, the mobility of the second active layer can be 15 cm²/Vs or more, and mobilities of the first active layer and the third active layer can be 14 cm²/Vs or less.

A transistor according to one embodiment of the present disclosure can further comprise a first source-drain electrode and a second source-drain electrode connected to the third active layer not overlapping with the gate electrode.

In a transistor according to one embodiment of the present disclosure, each of the first source-drain electrode and the second source-drain electrode can be connected to the active layer through a plurality of contact holes provided in parallel in a width direction of an overlapping region of the active layer and the gate electrode.

In a transistor according to one embodiment of the present disclosure, an upper surface and a side surface of the second active layer can be surrounded by the third active layer. The third active layer on the side surface of the second active layer can be in contact with the first active layer.

In a transistor according to one embodiment of the present disclosure, the second active layer can be located inside an edge of the gate electrode.

In a transistor according to one embodiment of the present disclosure, a region of the gate insulating film overlapping an edge of the gate electrode can be thicker than another region.

A transistor according to one embodiment of the present disclosure can further comprise a light-shielding pattern between a substrate and the active layer. The light-shielding pattern can be connected to the gate electrode at a region not overlapping with the active layer.

In a transistor according to one embodiment of the present disclosure, the light-shielding pattern can overlap the second active layer, and has a larger area than an area of the second active layer.

A display device according to one embodiment of the present disclosure can comprise a substrate comprising an active area and a non-active area and the transistor in at least one of the non-active area and a subpixel of the active area of the substrate.

In a display device according to one embodiment of the present disclosure, the transistor can be included in a gate-in-panel (GIP).

A display device according to one embodiment of the present disclosure can comprise a substrate having an active area and a non-active area, a plurality of gate lines and a plurality of data lines intersecting each other at the active area and defining a plurality of subpixels, a first transistor and a second transistor provided in at least one of the plurality of subpixels, a light emitting element connected to the second transistor and a third transistor at the non-active area. At least one of the first transistor, the second transistor and the third transistor can comprise three or more multiple layers, which comprise an active layer having a highest mobility in a middle layer, a gate electrode overlapping the active layer, and a gate insulating film between the active layer and the gate electrode.

In a display device according to one embodiment of the present disclosure, each of multiple layers of the active layer can comprise an oxide semiconductor layer including at least one metal, and the middle layer in the active layer can have a highest conductivity of the at least one metal compared to an upper layer (or upper layers) and/or a lower layer (or lower layers) of the active layer.

A display device according to one embodiment of the present disclosure can further comprise a first source-drain electrode and a second source-drain electrode connected to the active layer not overlapping with the gate electrode.

In a display device according to one embodiment of the present disclosure, each of the first source-drain electrode and the second source-drain electrode can be connected to the active layer through a plurality of contact holes provided in parallel in a width direction of an overlapping region of the active layer and the gate electrode.

In a display device according to one embodiment of the present disclosure, an upper surface and a side surface of the middle layer of the active layer can be surrounded by an upper layer on the middle layer, and the middle layer can be located inside an edge of the gate electrode.

It will be apparent to those skilled in the art that various modifications and variations can be made in the present disclosure without departing from the spirit or scope of the disclosure. Thus, it is intended that the present disclosure cover the modifications and variations of this disclosure provided they come within the scope of the appended claims and their equivalents.

What is claimed is:

1. A transistor comprising:
an active layer comprising a plurality of layers including a first active layer, a second active layer, and a third active layer that are sequentially stacked;
a gate electrode overlapping the active layer; and
a gate insulating film between the active layer and the gate electrode,
wherein the second active layer has a highest mobility among the plurality of layers of the active layer.

2. The transistor according to claim 1, wherein each of the first to third active layers includes an oxide semiconductor including one or more metals.

3. The transistor according to claim 1, wherein the second active layer includes at least one of FIZO (Fe—In—Zn-Oxide), ZnO (Zn-Oxide), and SnO (Sn-Oxide).

4. The transistor according to claim 1, wherein:
each of the first to third active layers includes IGZO (In—Ga—Zn-Oxide), the second active layer has an indium content ratio greater than a gallium content ratio, and
each of the first active layer and the third active layer has an indium content ratio less than or equal to a gallium content ratio.

5. The transistor according to claim 1, wherein:
the mobility of the second active layer is 15 cm²/Vs or more, and mobilities of the first active layer and the third active layer are 14 cm²/Vs or less.

6. The transistor according to claim 1, further comprising a first source-drain electrode and a second source-drain electrode connected to the third active layer not overlapping with the gate electrode.

7. The transistor according to claim 6, wherein each of the first source-drain electrode and the second source-drain electrode is connected to the active layer through a plurality of contact holes provided in parallel in a width direction of an overlapping region of the active layer and the gate electrode.

8. The transistor according to claim 1, wherein:
an upper surface and a side surface of the second active layer are surrounded by the third active layer, and
the third active layer on the side surface of the second active layer is in contact with the first active layer.

9. The transistor according to claim 1, wherein the second active layer is located inside an edge of the gate electrode at an overlapping region of the active layer and the gate electrode.

10. The transistor according to claim 1, wherein a region of the gate insulating film overlapping an edge of the gate electrode is thicker than another region of the gate insulating film.

11. The transistor according to claim 1, further comprising a light-shielding pattern between a substrate and the active layer,
wherein the light-shielding pattern is connected to the gate electrode at a region not overlapping with the active layer.

12. The transistor according to claim 11, wherein the light-shielding pattern overlaps the second active layer, and has a larger area than an area of the second active layer.

13. The transistor according to claim 1, wherein the second active layer serves as an intrinsic region.

14. A display device comprising:
a substrate comprising an active area and a non-active area; and
the transistor according to claim 1 in at least one of the non-active area and a subpixel of the active area of the substrate.

15. The display device according to claim 14, wherein the transistor is included in a gate-in-panel (GIP).

16. A display device comprising:
a substrate having an active area and a non-active area;
a plurality of gate lines and a plurality of data lines intersecting each other at the active area and defining a plurality of subpixels;
a first transistor and a second transistor provided in at least one of the plurality of subpixels;
a light emitting element connected to the second transistor; and
a third transistor at the non-active area,
wherein at least one of the first transistor, the second transistor and the third transistor comprises an active layer including three or more layers, a gate electrode overlapping the active layer, and a gate insulating film between the active layer and the gate electrode and
wherein the active layer has a highest mobility in a middle layer among the three or more layers.

17. The display device according to claim 16, wherein:
each of the three or more layers in the active layer comprises an oxide semiconductor layer including at least one metal, and
the middle layer in the active layer has a highest conductivity of the at least one metal compared to an upper layer and a lower layer among the three or more layers.

18. The display device according to claim 16, further comprising a first source-drain electrode and a second source-drain electrode connected to the active layer not overlapping with the gate electrode.

19. The display device according to claim 18, wherein each of the first source-drain electrode and the second source-drain electrode is connected to the active layer through a plurality of contact holes provided in parallel in a width direction of an overlapping region of the active layer and the gate electrode.

20. The display device according to claim 16, wherein:
an upper surface and a side surface of the middle layer of the active layer are surrounded by an upper layer disposed on the middle layer, and
the middle layer is located inside an edge of the gate electrode.
